(19) United States
(12) Patent Application Publication
(10) Pub. No.: US 2008/0111183 A1
(43) Pub. Date: May 15, 2008

(54) FLASH MEMORY DEVICE AND METHOD OF MANUFACTURING THE SAME

(76) Inventor: Jin-Hyo Jung, Gyeonggi-do (KR)

Correspondence Address: SHERR & NOURSE, PLLC, 620 HERNDON PARKWAY, SUITE 200, HERNDON, VA, 20170, US

(21) Appl. No.: 11/841,085

(22) Filed: Aug. 20, 2007

(30) Foreign Application Priority Data
Aug. 23, 2006 (KR) 10-2006-0080096

(51) Int. Cl. H01L 29/792; H01L 21/336

(52) U.S. Cl. 257/325; 438/287; 257/E21.423; 257/E29.309; 977/774

(57) ABSTRACT

A flash memory device and a method of manufacturing the same comprises source and drain diffusion regions formed at fixed intervals in an active area of a silicon semiconductor substrate, charge storage layers of multi-layers formed on the substrate, and a control gate formed on the charge storage layers, wherein the charge storage layers include a tunnel oxide film formed on the silicon semiconductor substrate, and a silicon nitride film formed on the tunnel oxide film, and the silicon nitride film includes a plurality of minute crystals formed by ion-implanting 14-group elements into the silicon nitride film. The flash memory device maintains the good programming and erasing operation of SONOS devices, and also improves trap density and memory window. Because of the difference of energy barrier between the minute crystal and the silicon nitride, the electrons or holes trapped in the minute crystal as the deep trap are not easily detrapped therefrom, thereby improving the data storage property of the device.

The present application claims priority under 35 U.S.C 119 to Korean Patent Application No. 10-2006-0080096, filed Aug. 23, 2006, which is hereby incorporated by reference in its entirety.

### BACKGROUND

In general, a flash memory is one kind of PROM (programmable ROM) which enables data to be rewritable electrically. The flash memory performs a program input method of an EPROM (Erasable PROM) and a program erase method of an EEPROM (Electrically Erasable PROM). An EPROM typically has a small cell area because each memory cell is comprised of one transistor. However, EPROMs have a disadvantage in that data can be erased by UV rays. In contrast, in the case of an EEPROM, it is only possible to electrically erase data; but EEPROMs have a disadvantage of a large cell area because its memory cell is comprised of two transistors. Also, a flash memory is different from DRAM (Dynamic RAM) and SRAM (Static RAM) in that it is considered a nonvolatile memory whose data is not lost even when a power supply is unintentionally stopped.

Based on cell-array architecture, the flash memory can be classified into a NOR-type structure where cells are arranged in parallel between a bit line and a ground or a NAND-type structure where cells are arranged in series therebetween. The NOR-type flash memory with the parallel structure is generally used for booting a mobile phone since it enables a high-speed random access on its reading operation. The NAND-type flash memory with the serial structure has a low reading speed, whereas it has a high writing speed. In this respect, the NAND-type flash memory is more appropriate for data storage and is also useful to achieve miniaturization. A flash memory may also be classified into a stack gate type and a split gate type on the basis of a unit cell structure. Based on a type of charge storage layer, the flash memory device may be classified into a floating gate device or a silicon-oxide-nitride-oxide-silicon (SONOS) device.

A SONOS device comprises a gate insulation layer which is formed of a charge storage layer in an ONO structure of silicon oxide film-silicon nitride film-silicon oxide film. In this case, since the SONOS device has charges trapped in a deep energy level of the silicon nitride film, the SONOS device has better reliability than a floating gate device. Furthermore, the SONOS device enables programming and erasing operations at a lower voltage level.

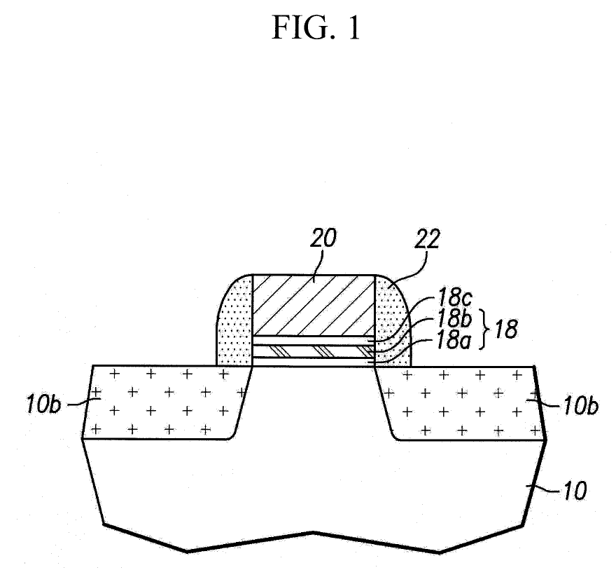

Example FIG. 1 is a cross section view of a SONOS structure. Referring to example FIG. 1, charge storage layers 18 are interposed between a substrate 10 and a control gate 20. The plurality of charge storage layers 18, which are multi layer structures, are comprised of a tunnel oxide film 18a, a silicon nitride film 18b and a blocking oxide film 18c sequentially stacked. The control gate 20 is formed on the plurality of charge storage layers 18. Also, spacer-shaped insulating films 22 are formed at both sidewalls of the control gate 20. In this case, reference numerals 10a and 10b correspond to source and drain diffusion regions.

In a flash memory device having the SONOS structure, a plurality of trap sites are formed in the silicon nitride film used as the charge storage layer. That is, electrons or holes are trapped in or detrapped from the trap sites, whereby a threshold voltage is changed in the SONOS device, thereby performing a memory operation. However, the SONOS device has limitations when used in a flash memory device due to the following problems.

Because the density of trap sites remaining in the silicon nitride film is low, the programming and erasing operation speed is low and, therefore, it is difficult to obtain a wide memory window. Due to the shallow energy level of trap sites remaining in the silicon nitride film, the trapped electrons or holes are discharged easily such that the data storage capacity becomes lower. Even though a SONOS device can be driven by the low voltage because the electrons or holes are trapped in the trap sites having the low energy level inside the silicon nitride film, this advantage adversely causes the disadvantage of low data storage capacity since the electrons or holes are detrapped easily.

### SUMMARY

Embodiments relate to an apparatus that includes charge storage layers. These charge storage layers, themselves, include a tunnel oxide film formed on a silicon semiconductor substrate; and a silicon nitride film formed on the tunnel oxide film, wherein the silicon nitride film includes a plurality of crystals formed by ion-implanting at least one of the 14-group elements of the periodic table into the silicon nitride film.

Embodiments also relate to a method that includes (a) sequentially forming a tunnel oxide film and a silicon nitride film on a silicon semiconductor substrate; (b) ion-implanting at least one of the 14-group elements of the periodic table into the silicon nitride film; and (c) forming a plurality of crystals including the at least one of the 14-group elements inside the silicon nitride film by applying a thermal treatment to the silicon semiconductor substrate.

### DRAWINGS

Example FIG. 1 is a cross section view to illustrate a flash memory device having a SONOS structure.

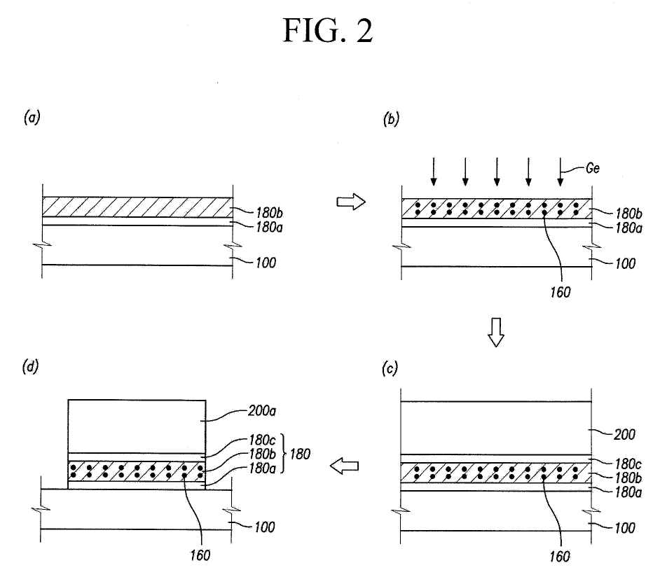

Example FIG. 2A through 2D are cross section views illustrating a method of manufacturing a flash memory device according to embodiments.

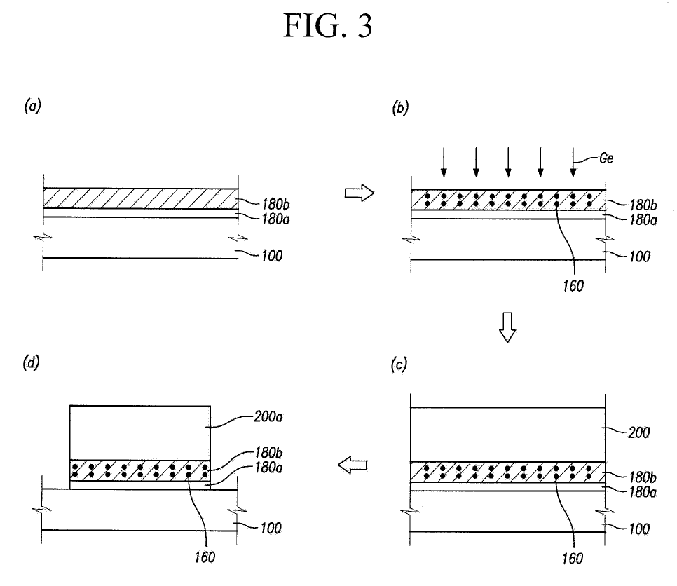

Example FIG. 3A through 3D are cross section views illustrating a method of manufacturing a flash memory device according to embodiments.

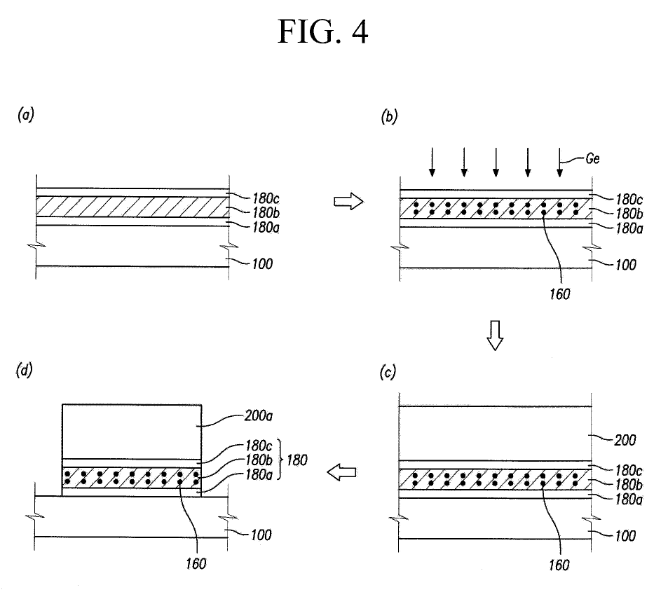

Example FIG. 4A through 4D are cross section views illustrating a method of manufacturing a flash memory device according embodiments.

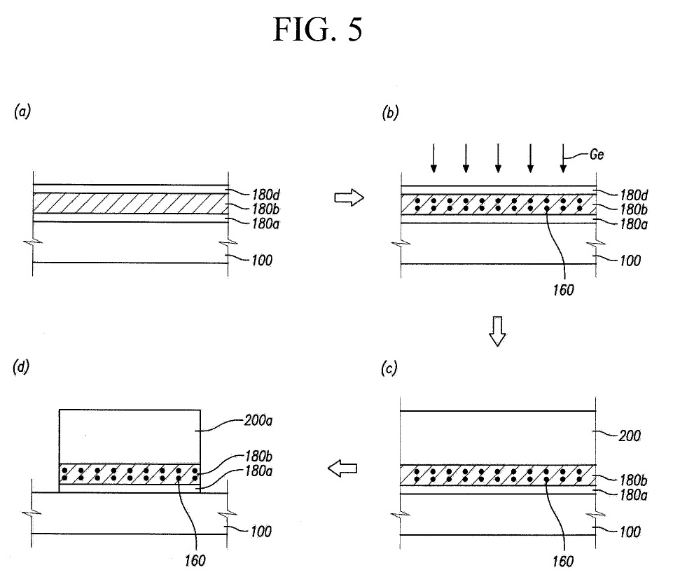

Example FIG. 5A through 5D are cross section views illustrating a method of manufacturing a flash memory device according to embodiments.

### DESCRIPTION

Example FIG. 2A through 2D are cross section views illustrating a method of manufacturing a flash memory device according to embodiments described herein.

First, as shown in example FIG. 2A, a silicon oxide film is formed at a thickness between approximately 15 Å and approximately 40 Å on a silicon semiconductor substrate 100, wherein the silicon oxide film functions as a tunnel oxide film 180a. In this case, the silicon oxide film 180a may be a thermal oxide film formed by oxidizing the substrate 100, or may be deposited by chemical vapor deposition (CVD) or physical vapor deposition (PVD). After forming the tunnel oxide film 180a, a silicon nitride film 180b is formed by CVD or PVD, wherein the silicon nitride film 180b is formed at a thickness between approximately 50 Å and approximately 250 Å. The silicon nitride film 180b is used as a charge storage layer where electrons or holes are trapped or detrapped in operation of a flash memory device. Generally, the tunnel oxide film 180a, the silicon nitride film 180b, and a blocking oxide film (formed by the successive process) constitute a SONOS structure.

The silicon nitride film of the SONOS structure has an energy band gap of about 5 eV. Also, an energy level of a trap site for electrons or holes formed inside the silicon nitride film has an energy gap of about 1 eV from a conduction band or valance band of the silicon nitride. Accordingly, as mentioned above, when using the silicon nitride film as the charge storage layer in the same method as in the related art SONOS structure, the electrons or holes trapped in the trap site are easily discharged. However, in case of a flash memory device according to the embodiments described herein, the trap site has a deeper energy level than that of the related art trap site, formed inside the silicon nitride film used as the charge storage layer, as explained in detail below.

As shown in example FIG. 2B, 14-group elements of the periodic table (for example, germanium Ge) except silicon are ion-implanted into the inside of silicon nitride film 180b. If the 14-group elements implanted into the inside of silicon nitride film 180b are crystallized by a thermal treatment applied to the substrate, a plurality of minute crystals 160 inside the silicon nitride film 180b form as a cluster. The temperature of the thermal treatment is beneficially above a crystallization temperature of the 14-group elements implanted into the inside of silicon nitride film 180b. The minute crystals 160 formed in the silicon nitride film 180b may be approximately nano-size (in other words, on the scale of nanometers or tens or hundreds of nanometers; although larger crystals may be formed as well). Also, the minute crystals 160 may be regularly arranged inside the silicon nitride film 180b.

An energy band gap of minute crystal 160 may be included within the energy band gap of silicon nitride. That is, the energy level of conduction band of minute crystal 160 is lower than the conduction band gap of silicon nitride and the energy level of valance band of minute crystal 160 is higher than the energy level of valance band of silicon nitride. Thus, the energy band gap of minute crystal 160 may be smaller than the energy band gap of silicon nitride. For example, if the minute crystal comprises germanium (Ge), the energy band gap of GE is about 0.7 eV and the conduction band and valance band exist within the energy band gap of silicon nitride.

Due to the irregular trap sites formed in the silicon nitride used as the charge storage layer in the related art SONOS structure, the memory window is not constant when operating the flash memory device. In contrast, according to embodiments described herein, when the silicon nitride film including the minute crystals is used as the charge storage layer of the SONOS device, the memory window is maintained constant, thereby improving the reliability of device.

Next, as shown in example FIG. 2C, the blocking oxide film 180c is formed on the silicon nitride film 180b, and a polysilicon film 200 of a conductive film is formed on the blocking oxide film 180c. When the conductive film 200, the blocking oxide film 180c, the silicon nitride film 180b and the tunnel oxide film 180a are etched in sequence, as shown in example FIG. 2D, the SONOS structure is completed, and is comprised of the control gate 200a, the blocking oxide film 180c, the silicon nitride film 180b and the tunnel oxide film 180a. After that, through the general fabrication process, spacers are formed at both sidewalls of the control gate 200a, and source and drain diffusion regions are formed in an active region of the substrate, wherein the source and drain diffusion regions are separated with a predetermined interval, thereby completing the flash memory device.

Example FIG. 3A through 3D are cross section views illustrating a method of manufacturing a flash memory device according to embodiments described herein.

In the method illustrated in example FIGS. 3A-3D, steps of forming a tunnel oxide film 180a and a silicon nitride film 180b (that is, a step shown in example FIG. 3A) and forming a plurality of minute crystals 160 in the silicon nitride film 180b (that is, a step shown in example FIG. 3B) are similar to steps shown in example FIGS. 2A and 2B. In this method of example FIG. 3, the silicon nitride film 180b is deposited at a thickness between approximately 100 Å and approximately 500 Å. However, in a step of example FIG. 3C, instead of forming a blocking oxide film, a conductive film 200 is formed on the silicon nitride film 180b. At this time, the silicon nitride film 180b described previously. As a result and as intended, this thicker silicon nitride film 180b has a blocking effect. Thus, the flash memory device illustrated in example FIGS. 3A-3C includes a SONS structure which has no blocking oxide film therein. After that, as shown in example FIG. 3D, the conductive film 200, the silicon nitride film 180b and the tunnel oxide film 180a are etched in sequence, to thereby form a control gate 200a.

Example FIG. 4A through 4D are cross section views illustrating a method of manufacturing a flash memory device according to embodiments described herein.

As shown in example FIG. 4A, a tunnel oxide film 180a and a silicon nitride film 180b are formed on a substrate 100 under the same conditions as those described earlier with respect to example FIG. 2. Then, a blocking oxide film 180c is formed on the silicon nitride film 180b. The blocking oxide film 180c may be formed at a thickness between approximately 30 Å and approximately 80 Å. After that, as shown in example FIG. 4B, germanium (Ge) ions are implanted into the silicon nitride film 180b. The blocking oxide film 180c operates to prevent lattice defects from occurring in the surface of the silicon nitride film 180b as a result of the ion-implantation process. That is, according to the sequence of example FIG. 2 germanium (Ge) ions are directly implanted on the silicon nitride film 180b, whereby the surface of silicon nitride film 180b may be damaged. In the sequence of example FIG. 4, however, the blocking oxide film 180c prevents the surface of the silicon nitride film 180b from being damaged, thereby improving the reliability of device.

After that, as shown in example FIG. 4C, a conductive film 200 may be formed on the blocking oxide film 180c. Then, as shown in example FIG. 4D, a SONOS structure including a control gate 200a is completed by patterning.

Example FIG. 5A through 5D are cross section views illustrating a method of manufacturing a flash memory device according embodiments described herein.

According to these figures, a tunnel oxide film 180a and a silicon nitride film 180b are formed under the same conditions as those described with respect to example FIG. 3. Before germanium (Ge) ions are implanted into the silicon nitride film 180b, as shown in example FIG. 5A, a protective oxide film 180d is additionally formed on the silicon nitride film 180b. The protective oxide film 180d is formed at a thickness between approximately 50 Å and approximately 200 Å. As shown in example FIG. 5B, after minute crystals 160 are formed in the silicon nitride film 180b through the Ge-ion implantation process and thermal process, the protective oxide film 180d is removed. Then, as shown in example FIG. 5C, a conductive film 200 is formed on the silicon nitride film 180b. The silicon nitride film 180b is twice or more as thick as that of the silicon nitride film of the related art SONOS structure. Accordingly, the silicon nitride film 180b provides a blocking effect by itself without the presence of an additional blocking oxide film. After that, as shown in example FIG. 5D, an SONOS structure including a control gate 200a is completed by patterning.

It will be apparent to those skilled in the art that various modifications and variations can be made without departing from the spirit or scope of the embodiments described herein. For example, in case of the structure described with respect to example FIG. 4, after a protective oxide film is formed on a silicon nitride film, and minute crystals are formed in the silicon nitride film, the protective oxide film may be removed. Furthermore, a blocking oxide film is formed on the silicon nitride film being exposed by removing the protective oxide film, thereby completing an SONOS structure.

As mentioned above, the flash memory device and the method of manufacturing such a device, as described herein, have the following advantages.

Because minute crystals that have a smaller energy band gap than that of the silicon nitride are formed in the silicon nitride film used as the charge storage layer of the related art SONOS device, it is possible to form a stable trap site. The improvements in the trap density and the memory window provide benefits during programming and erasing operations. Especially, owing to the difference of energy barrier between the minute crystal and the silicon nitride, the electrons or holes trapped in the minute crystal, acting as the deep trap, are not easily detrapped therefrom, thereby improving the data storage characteristics of the device.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising charge storage layers comprising:
a tunnel oxide film formed on a silicon semiconductor substrate; and
a silicon nitride film formed on the tunnel oxide film, wherein the silicon nitride film includes a plurality of crystals formed by ion-implanting at least one of the 14-group elements of the periodic table into the silicon nitride film.

2. The apparatus of claim 1, further comprising source and drain diffusion regions formed at fixed intervals in an active area of the silicon semiconductor substrate.

3. The apparatus of claim 1, further comprising a control gate formed on the charge storage layers.

4. The apparatus of claim 1, wherein a size of the plurality of crystals is between approximately 1 and approximately 900 nanometers.

5. The apparatus of claim 1, wherein the plurality of crystals are regularly arranged within the silicon nitride film.

6. The apparatus of claim 1, wherein the charge storage layers further comprise a blocking oxide film formed on the silicon nitride film.

7. The apparatus of claim 1, wherein an energy band gap in the plurality of minute crystals is smaller than an energy band gap in silicon nitride.

8. The apparatus of claim 6, wherein an energy band gap in the plurality of minute crystals is smaller than an energy band gap in silicon nitride.

9. The apparatus of claim 1, wherein the at least one of the 14-group elements comprises germanium (Ge).

10. The apparatus of claim 1, wherein the at least one of the 14-group elements is selected from the group: tin (Sn) and lead (Pb).

11. The apparatus of claim 1, wherein the apparatus is a flash memory device.

12. A method comprising:
sequentially forming a tunnel oxide film and a silicon nitride film on a silicon semiconductor substrate;
ion-implanting at least one of the 14-group elements of the periodic table into the silicon nitride film; and
forming a plurality of crystals including the at least one of the 14-group elements inside the silicon nitride film by applying a thermal treatment to the silicon semiconductor substrate.

13. The method of claim 12, comprising:
forming a conductive film on the silicon nitride film including the plurality of crystals; and
forming a plurality of charge storage layers and a control gate by sequentially patterning the conductive film, the silicon nitride film and the tunnel oxide film.

14. The method of claim 13, comprising:
forming a blocking oxide film on the silicon nitride film, wherein the conductive film, the blocking oxide film, the silicon nitride film and the tunnel oxide film are sequentially patterned.

15. The method of claim 13, comprising:
forming a protective oxide film on the silicon nitride film in the step before ion-implanting; and
removing the protective oxide film before forming the conductive film.

16. The method of claim 15, comprising forming a blocking oxide film on the silicon nitride film being exposed by removing the protective oxide film before forming the conductive film, wherein the conductive film, the blocking oxide film, the silicon nitride film and the tunnel oxide film are sequentially patterned.

17. The method of claim 13, comprising forming a blocking oxide film on the silicon nitride film, wherein the conductive film, the blocking oxide film, the silicon nitride film and the tunnel oxide film are sequentially patterned.

18. The method of claim 13, wherein an energy band gap in the plurality of crystals formed in the silicon nitride film is smaller than an energy band gap in silicon nitride.

19. The method of claim 13, wherein the at least one of the 14-group elements implanted into the silicon nitride film comprises germanium (Ge).

20. The method of claim 12, wherein a size of the plurality of crystals is between approximately 1 and approximately 900 nanometers.
